(19) United States
(12) Patent Application Publication
(10) Pub. No.: US 2016/0381468 A1
(43) Pub. Date: Dec. 29, 2016

(54) METHOD FOR COMPRESSING THE DYNAMICS IN AN AUDIO SIGNAL

(71) Applicant: SIVANTOS PTE. LTD., SINGAPORE (SG)

(72) Inventors: STEFAN PETRAUSCH, ERLANGEN (DE); ULRICH GIESE, ERLANGEN (DE); SEBASTIAN PAPE, ERLANGEN (DE)

(21) Appl. No.: 15/191,795

(22) Filed: Jun. 24, 2016

(30) Foreign Application Priority Data
Jun. 24, 2015 (DE) 10 2015 211 745.6

(51) Int. Cl. H04R 25/00; H03G 7/00

(52) U.S. Cl. CPC H04R 25/505; H03G 7/002

(57) ABSTRACT

A method for compressing the dynamics in an audio signal includes measuring at least one input level of the audio signal and comparing the measured input level with a limit value. A prescribed compression characteristic having a knee defined by a base value of the input level is adjusted to suit the audio signal by raising the knee from the base value to a higher target value if the at least one input level exceeds the limit value. The audio signal is compressed in accordance with the adjusted compression characteristic. A signal processing unit includes a signal input for feeding in an audio signal and is configured to perform the method, and a hearing device includes at least one microphone for obtaining an audio signal from an ambient sound and the signal processing unit connected to the microphone.

### CROSS-REFERENCE TO RELATED APPLICATION

This application claims the priority, under 35 U.S.C. §119, of German Patent Application DE 10 2015 211 745.6, filed Jun. 24, 2015; the prior application is herewith incorporated by reference in its entirety.

### BACKGROUND OF THE INVENTION

Field of the Invention

The invention relates to a method for compressing the dynamics in an audio signal that is obtained from an ambient sound or is fed in by an audio source, for example. In this case, the audio signal is the signal from which an aural signal is generated for a user. The invention also relates to a signal processing unit for performing the method and a hearing device or hearing aid having the signal processing unit.

In signal processing for an audio signal, compression of the dynamics is often an important tool to allow adequate mapping of a sound signal having large level differences, and hence a large dynamic range. In the event of purely linear amplification of the audio signal, large differences in the level of the sound signal to be recorded and to be processed can result either in the signal components with the largest level deflections at a point in the signal processing leading to overload when the gain factor is chosen to be too high or in signal components with a low signal level not being satisfactorily, particularly not being sufficiently audibly, represented in a fully processed output signal when the gain factor is chosen to be too low.

In the field of hearing devices, compression of the dynamics is a way of adjusting the aural signal to suit the limited hearing of an aurally handicapped person. The hearing of an aurally handicapped person has a limited dynamic range, which means that small input levels need to be amplified by a large amount. For large input levels, however, the gain needs to be lowered, because the aural signals amplified in that manner are otherwise perceived as disagreeably loud.

In that case, compression of the dynamics of the audio signal counters that by using a level-dependent gain factor for amplification. In most cases, the compression characteristic, represented by the characteristic curve, which indicates the ratio of input level to output level, has a linear gain by a constant factor up to a particular threshold of the input level, while the gain is lowered on a level-dependent basis for input levels beyond the threshold. If input level and output level are plotted against one another in decibels, that then results in a profile that is linear in places as a compression characteristic, with the characteristic curve having a lower gradient upward of the threshold for the input level. In that case, the deviation in that gradient from a diagonal profile determines the compression ratio r<1 by which the input level is compressed beyond the threshold.

In a noisy environment having an average sound level which has a corresponding signal level that is close to that threshold, speakers in most cases tend to react to the higher noise level in the environment by speaking louder. In the case of dynamics compression having a threshold which is oriented to speaking at normal volume, that means that the now louder speech is captured as a useful signal component by the compression, which undesirably decreases the signal-to-noise ratio. The same applies to other ambient sound or direct audio signals from audio sources, wherein an inherently loud useful or target signal is meant to be picked out from a raucous, noisy or other background sound, such as e.g. the signal from a single musical instrument or the like. By compressing the audio signal obtained from the useful signal or an audio signal that directly contains the useful signal, the sound of the useful signal can be perceived as unnatural and even disagreeable in the compressed audio signal. In particular, that can occur with a fast attack and/or release for the compression.

### SUMMARY OF THE INVENTION

It is accordingly an object of the invention to provide a method for compressing the dynamics in an audio signal, a signal processing unit and a hearing device, which overcome the hereinafore-mentioned disadvantages of the heretofore-known methods, units and devices of this general type and which allow the most flexible possible reaction to environments with different loudnesses and at the same time are intended to have the most natural possible sound particularly for clearly definable useful signals, such as spoken language.

With the foregoing and other objects in view there is provided, in accordance with the invention, a method for compressing the dynamics in an audio signal, which comprises measuring at least one input level of the audio signal, comparing the measured input level with a limit value, adjusting or adapting a prescribed compression characteristic having a knee defined by a base value of the input level to suit the audio signal by raising the knee from the base value to a higher target value if the at least one input level exceeds the limit value, and compressing the audio signal in accordance with the adjusted or adapted compression characteristic.

In particular, a knee of the compression characteristic is intended to be understood in the present case to mean that for an input level up to the abscissa value that defines the knee, the output level is provided by the input level amplified by a constant gain factor, and for input levels beyond this abscissa value, the gain decreases on the basis of the input level. This particularly includes the compression characteristic beyond the knee having a compression ratio that is itself dependent on the input level and possibly constant in sections. In the present case, for the prescribed compression characteristic, the abscissa value defining the knee is provided by the base value, and the abscissa value defining the knee of the adjusted compression characteristic is provided by the target value.

In this case, the invention is based on the consideration that in an audio signal that is to be processed, particularly in the case of a useful signal with appreciable background noise, other ambient or additional sounds or din, short time constants for attack and release with heavy compression, that is to say compression of the input level using a comparatively high compression ratio, can result in an unnatural or even disagreeable aural perception. A speaker often reacts to a brief, temporary rise in the level of the ambient or background sounds by speaking louder. If, in an environment in which such changes in the level can take place, an audio signal having a useful signal which is formed by spoken language now needs to be recorded for further processing, then the input level has significant variations over a wide dynamic range that affect particularly the useful signal. The same applies in an appropriate manner to music signals or other audio signals having useful or target signals with levels which have large variations.

If the compression characteristic is now configured primarily for a particular aural or ambient situation, i.e. if compression in the sense of level-dependent attenuation of the audio signal begins at a particular preset input level that corresponds to or is chosen to be just above an average value that is to be expected for the level of the useful signal, for example, then this leads to undesirable heavier compression of the useful signal. If the attack/release time constants are retained, the now louder useful signal would thus be attenuated to a comparatively greater degree per unit time, which is undesirable due to the resultant aural perception of a fully processed audio signal. However, an adjustment to suit the heavier compression of the temporarily higher input level by using an extension of the relevant time constants could lead to brief level peaks in the audio signal with an input level that is increased anyway now not being intercepted in good time and hence being able to produce an overload as a result of the gain.

By contrast, the invention proposes that a brief, temporary increase in the input level prompts a prescribed compression characteristic to be adjusted to suit this increase by virtue of the knee of the compression characteristic being appropriately shifted toward a higher value for the input value, and the time constants of the compression themselves not being altered a priori in this case. In order to prevent unnecessary jumping or an excessively fast response for the adjustment, the input level is compared with a limit value that needs to be selected as appropriate, and the adjustment is performed only when the limit value is exceeded. Preferably, this prompts a limit value of between 55 dB and 70 dB to be chosen for the input level of a wideband input signal. In the case of channel-dependent, that is to say frequency-resolved, consideration of the input signal, a limit value of between 40 dB and 55 dB is preferably chosen in the respective channel. In this case, the chosen limit values correspond particularly to a typical noise situation.

In a preferred variant, the knee is raised to a predetermined target value. In this case, the predetermined target value is based on empirical values and is chosen particularly on the basis of a given aural situation or a given specific audio signal, such as a music signal, for example.

In another advantageous variant, the knee is raised to a target value that is dependent on the input level. In this case, the input level is captured particularly in a manner averaged over a time range. If the limit value for the, in particular, averaged, input level is exceeded, then the target value is increased on the basis of the captured or averaged and captured input level. In other words, the magnitude of the target value to which the knee is raised is adaptively tracked to the current input level or the currently averaged input level. By way of example, the target value for the knee is tracked to the mean input level of a level meter that has a slow attack and release response. As a result, in a preferred refinement, it is possible for the knees to be approximately 3 dB below the useful-signal-relevant signal peaks.

Further, an attack time for comparison of the input level with the limit value can be chosen or set in such a way that extremely brief level peaks that do not stem from an increase in the general noise level do not lead to the compression characteristic being adjusted, but rather, although the comparison process reacts to changes sufficiently quickly due to the attack time, these changes need to be of a certain duration in order to initiate the adjustment.

Advantageously, raising of the knee of the compression characteristic prompts a total gain to be lowered in order to compensate. Preferably, the total gain is then lowered in such a way that for the input level that defines the new knee, the lowering of the total gain means that the output level is maintained in comparison with the originally prescribed compression characteristic for this input level. This alters the perception of volume only for input levels that are below the knee. A compression characteristic that is configured for higher average volumes in the input level as a result of the increase in the knee is accordingly, by lowering of the total gain (linear component), mapped onto the dynamic profile determined by the originally prescribed compression characteristic in order to compensate. Preferably, the total gain is lowered by decreasing the linear gain component in the compression characteristic. In other words, a lower gain is applied in comparison with the original characteristic in the range of low input levels, the knee is shifted for a larger value of the input level and the original gain is retained in the range of higher input levels. Since the perception of volume is maintained for input levels beyond the target value for the knee in this case, an agreeable aural perception with significantly fewer control artifacts and less amplification of ambient noise or other undesirable background sounds is achieved.

Preferably, the knee is lowered to the base value in order to adjust the compression characteristic to suit the audio signal if, after the limit value has been exceeded, the input level drops below the limit value again. This allows a reaction to a renewed decrease in the average sound level of noise and background sounds in the ambient sound, so that the compression remains adjusted to suit the respectively relevant dynamic range. In particular, this can involve previous lowering of a total gain in order to compensate for a raise of the knee of the compression characteristic being reversed, and, in particular, a time constant can be used to check the drop below the limit value, so that there is deemed to have been a renewed drop below the limit value only when, after the limit value has been exceeded, the input level remains below the limit value for the full duration of the time constant of the input level.

Expediently, compression of the audio signal involves a time constant for attack and/or a time constant for release being determined adaptively on the basis of the input level. The adaptive determination of the attack and/or release time constants for a compression on the basis of the input level allows an agreeable aural perception, since the effects of the compression on the useful signal component and background noise can be taken into account in the audio signal in equal measure, and a very rapid attack for the compression can often be perceived as unnatural. Adaptive determination of the attack and/or release time constants means that overload or over-amplification can be prevented for a signal component of the audio signal with a suddenly occurring, very high input level by using a short attack time, but a more natural sound can be obtained by using a somewhat longer attack time for a moderate deflection in the input level.

It is found to be a further advantage if the comparison of the measured input level with the limit value has a longer attack time and/or a longer release time than the time constant of attack or the time constant of release for compression. In particular, this can mean that exceeding of the limit value for the attack time requires the input level to be above the limit value throughout the attack time.

Since a shorter time constant is chosen for attack and for release of the compression than for comparison of the input level with the limit value, this allows very brief, sudden changes in the level of the signal that carries the useful signal to be prevented from leading to adjustment of the compression characteristic. The effects of such changes in an output signal are controlled by the compression itself, with the short time constants for attack and release also being able to be determined adaptively and hence a certain variation being possible within particular intervals. If a rise in the level of the signal is of longer duration, however, for example speaking in an environment that is becoming louder, then it can possibly be assumed that the short-term dynamic response and hence the level deflections, that is to say emphasis and phrasing by the speaker, etc., in the present example, also follow the rise, which is why adjustment of the compression characteristic is advantageous in this case.

In an additionally advantageous refinement of the invention, the audio signal is broken down into a plurality of frequency bands, wherein in each group of frequency bands, for each frequency band in the group, an input level of a signal component of the audio signal is measured in the frequency band, the measured input level is compared with a frequency-band-specific limit value, a compression characteristic prescribed for the frequency band is adjusted to suit the signal component, and the signal component is compressed in accordance with the adjusted compression characteristic. In particular, the group may in this case also include just one frequency band, so that the described adjustment of the prescribed compression characteristic to suit the signal component is performed on the basis of the input level just in one frequency band, while such adjustment does not occur in other frequency bands. However, the adjustment can also be performed for a plurality of frequency bands, particularly also for all frequency bands of the broken-down audio signal. In particular, the frequency-band-specific limit value for the input level and/or the prescribed compression characteristic may each be identical for a plurality of frequency bands.

Frequency-band-specific adjustment of the compression characteristic allows better consideration to be given particularly to certain signal components of customary noise, or noise that is to be expected depending on the aural situation, in individual frequency bands and the dynamic response thereof. In particular, the adjustment can also be effected on a frequency-band-specific basis in this case, i.e. the knee can be raised in individual frequency bands to different target values in each case, for example. In particular, comparison of the input level of the signal component in the respective frequency band with the frequency-band-specific limit value can also involve the individual attack times and/or release times varying across the frequency bands. The frequency-band-specific adjustment of the parameters allows the available resources such as computation power to be optimized for the most realistic aural perception possible.

With the objects of the invention in view, there is also provided a signal processing unit that is configured to perform the method described above and a signal input for feeding in an audio signal. In this case, the advantages specified for the method and the developments thereof can be logically applied to the signal processing unit. In particular, the signal processing unit may to this end be equipped with an appropriately set-up processor, and/or can process an appropriately compressed audio signal further and/or output it at a signal output.

With the objects of the invention in view, there is concomitantly provided a hearing device, particularly a hearing aid, comprising at least one microphone for obtaining an audio signal from an ambient sound, and a signal processing unit of the type described above connected to the microphone. The compression of the dynamics of the audio signal that the signal processing unit in the hearing device allows is particularly advantageous, in a hearing device, particularly against the background of frequently changing aural situations with different dynamics and the demand for a natural sound of the highest possible quality.

Other features which are considered as characteristic for the invention are set forth in the appended claims.

Although the invention is illustrated and described herein as embodied in a method for compressing the dynamics in an audio signal, a signal processing unit and a hearing device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a block diagram used to show the flow for a method for compressing the dynamics in an audio signal;

FIG. 2 is a level graph used to show the compression characteristic that is adjusted by the method shown in FIG. 1; and

FIG. 3 is a diagrammatic plan view of a hearing aid.

### DETAILED DESCRIPTION OF THE INVENTION

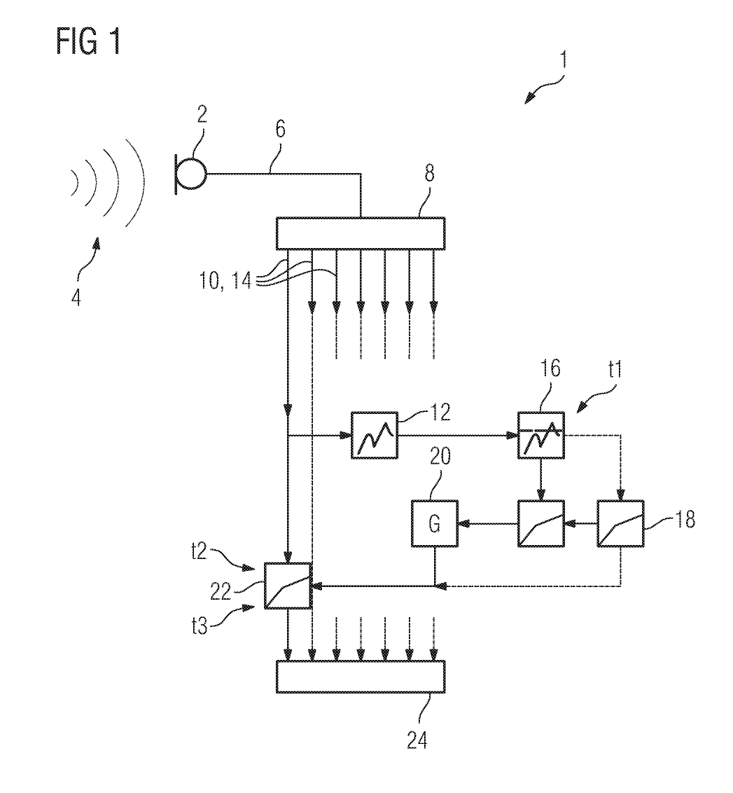

Referring now in detail to the figures of the drawings, in which mutually corresponding parts and parameters are each provided with the same reference symbols, and first, particularly, to FIG. 1 thereof, there is seen a block diagram which is used to schematically show the flow of a method 1. A microphone 2 obtains an audio signal 6 from an ambient sound 4 that is formed by a voice signal, which is not shown in more detail. The voice signal is overlaid with din or noise. Alternatively, the audio signal 6 is available as a signal played by an audio source directly, for example as a music signal, with the useful signal (for example the signal from a single musical instrument or the voice of a performer) again being overlaid with background sounds. The audio signal 6 is broken down into a plurality of frequency bands 10 in a filter bank 8. In each of the individual frequency bands 10, a respective input level 12 of a signal component 14 of the audio signal 6 in the frequency band 10 is then measured. The input level 12 of the signal component 14 is compared with a limit value 16 that is specifically prescribed for the frequency band 10, with a time constant t1 being provided for the process of comparison. If the input level 12 averaged over the time constant t1 exceeds the limit value 16 prescribed for the frequency band 10, a compression characteristic 18 prescribed for the frequency band 10 is adjusted to suit the signal component 14 of the audio signal 6 in the frequency band 10 in a manner that is yet to be described. In other words, the time constant t1 is used to stipulate the adjustment speed for the compression characteristic 18. Additionally, this adjustment of the compression characteristic 18 is compensated for by lowering a total gain 20 in the frequency band 10. The signal component 14 of the audio signal 6 in the frequency band 10 is then compressed in accordance with a compression characteristic 22 adjusted in this manner. A time constant t2 for an attack and a time constant t3 for a release of the compression in accordance with the adjusted compression characteristic are particularly chosen to be shorter than the time constant t1 for the comparison of the input level 12 with the limit value 16 in this case.

If the input level 12, measured in the frequency band 10, of the signal component 14 does not exceed the limit value 16, or exceeds it only for a period significantly shorter than the time constant t1, then the compression characteristic 18 prescribed for the frequency band 10 is defined in an unchanged manner as the compression characteristic 22 adjusted to suit the signal component 14, and the signal component 14 is compressed as appropriate in accordance with the adjusted compression characteristic 22. The same happens when, after the input level 12 of the signal component 14 has previously exceeded the limit value 16, there is a renewed drop below the frequency-band-specific limit value 16 for a period that is longer than that prescribed by the time constant t1.

The diagram shows the adjustment of the compression characteristic 18 by way of example for one of the frequency bands 10. Following the compression in accordance with the adjusted compression characteristic 22, the individual signal components 14 of the frequency bands 10 can be supplied to a further signal processing block 24, in which the signal components 14 of the audio signal 6 are processed further on a frequency-band-specific or wideband basis. In this case, the signal processing block 24 can include methods for noise suppression, for example.

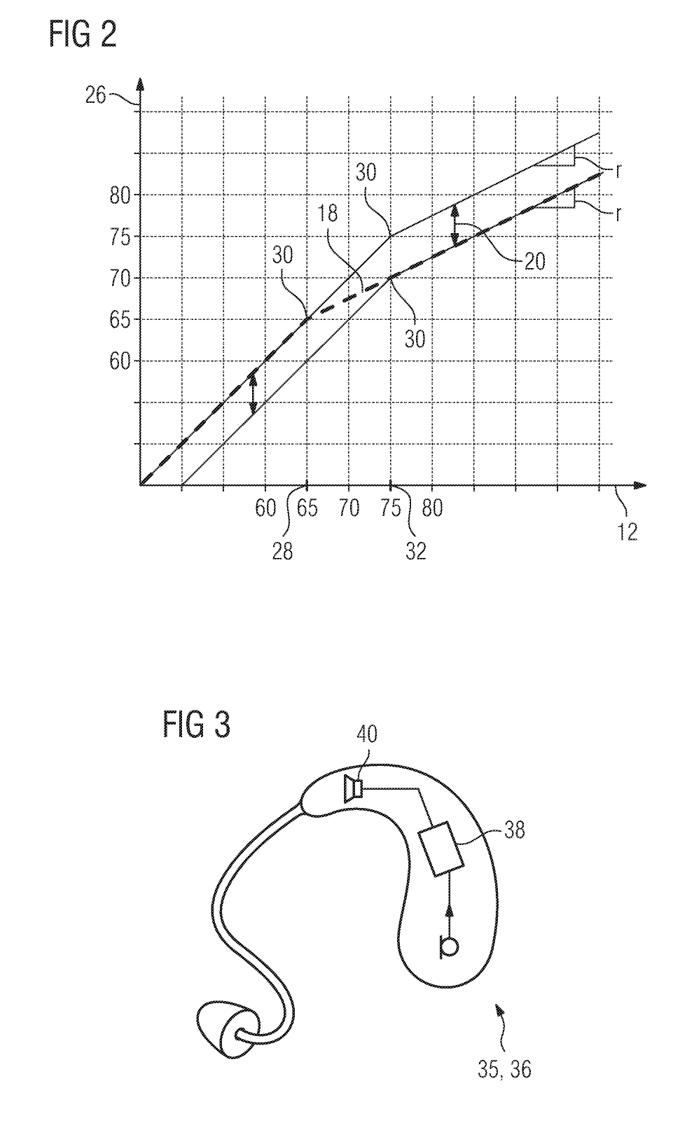

FIG. 2 shows a level graph for an exemplary adjustment of a compression characteristic 18, 22 using the method shown in FIG. 1. In this case, an output level 26 resulting from the compression is plotted against the input level 12. The dashed characteristic curve corresponds to the compression characteristic 18 originally prescribed for a wideband audio signal 6 in the event of the input level 12 not exceeding the prescribed limit value 16. In this case, the prescribed compression characteristic 18 has a linear profile with a constant gain by a gain factor 1 up to a base value 28 for the input level, which is a value of 65 dB in the present case. This means that a signal component in the audio signal 6 having an input level which does not exceed 65 dB is forwarded identically by the compression block in a signal processing.

The base value 28 for the input level 12 defines a knee 30 of the compression characteristic 18. Signal components having an input level 12 of greater than 65 dB are attenuated with a compression ratio of r=½ on the basis of the input level, as a result of which the compression characteristic 18 bends at the knee 30. The adjustment, shown in FIG. 1, of the compression characteristic 18 to suit the input level 12 of the signal component 14 then first of all provides for an instance of the limit value 16 being exceeded by the captured and, in particular, averaged input level 12 to prompt activation of the compression at r= ½ only for higher values of the input level 12 than are provided by the base value 28. To this end, the knee 30 is raised from the base value 28 to a target value 32, which in the present case is 75 dB. This means that no compression now takes place for signal components having an input level 12 of up to 75 dB, but rather the compression is activated only for an input level above 75 dB, and accordingly signal components 14 are compressed using a similar dependency on the input level 12, to that provided by the characteristic curve of the compression characteristic 18. This dependency is represented by the dotted line in the graph.

Since shifting the knee 30 to a higher target value 32 for the input level 12 effectively prompts the signal power to rise for an input level 12 above the base value 28, to compensate, the total gain 20 is lowered so that the characteristic curve of the adjusted compression characteristic 22, which is represented by a solid line in the graph, matches the characteristic curve of the prescribed compression characteristic 18 for values of the input value 12 above the target value 32. As a result, an aural situation in which an ambient sound 4 carries spoken language as a useful signal that is overlaid with loud perturbing sounds, can have a similar signal-to-noise ratio to a comparable useful signal in a less noisy environment.

As a result of the total gain 20 being lowered, in the present case by 5 dB, signal components in the adjusted compression characteristic 22 having an input level 12 below the base value 28 of 65 dB are accordingly lowered by 5 dB in comparison with the prescribed compression characteristic 18. In the transition region between the base value 28 and the target value 32 for the input level 12, this lowering turns out to be correspondingly smaller in comparison with the prescribed compression characteristic 18. However, since it is assumed that this lowering relates primarily to perturbing sounds and background noise from the environment, but not the useful signal, it is therefore possible to achieve an improvement in the signal-to-noise ratio.

The limit value 16 chosen for a wideband audio signal 6 as shown in FIG. 2, after which an, in particular, adaptive adjustment of the compression characteristic 22 is performed, is 70 dB, for example. By way of example, the adaptive adjustment is effected by choosing the target value 32 on the basis of the measured, that is to say in particular averaged, value of the input level 12. By way of example, the target value for the knee is tracked to the mean input level of a level meter that has a slow attack and release response. The result preferably achieved by this is that the knees are approximately 3 dB below useful-signal-relevant signal peaks.

FIG. 3 shows a hearing device 35 that is in the form of a hearing aid 36. The hearing aid 36 includes a microphone 2 for obtaining an audio signal 6 from an ambient sound 4, a signal processing unit 38 that is connected to the microphone 2 and into which the audio signal 6 is fed, and a loudspeaker 40 that is connected to the signal processing unit 38. In this case, the signal processing unit 38 is particularly set up to compress the audio signal 6 obtained by the microphone 2 from an ambient sound 4 on the basis of the input level using the prescribed method, and to forward a correspondingly compressed output signal to the loudspeaker 40 for reproduction.

Although the invention has been illustrated and described in more detail by the preferred embodiment, the invention is not restricted by this exemplary embodiment. Other variations can be derived therefrom by a person skilled in the art without departing from the scope of protection of the invention.

1. A method for compressing the dynamics in an audio signal, the method comprising the following steps:
measuring at least one input level of the audio signal;
comparing the measured input level with a limit value;
adjusting a prescribed compression characteristic having a knee defined by a base value of the input level to the audio signal by raising the knee from the base value to a higher target value if the at least one input level exceeds the limit value; and
compressing the audio signal in accordance with the adjusted compression characteristic.

2. The method according to claim 1, wherein the raising of the knee of the compression characteristic prompts a total gain to be lowered in order to compensate.

3. The method according to claim 1, which further comprises raising the knee to a predetermined target value.

4. The method according to claim 1, which further comprises raising the knee to a target value being dependent on the input level.

5. The method according to claim 1, which further comprises lowering the knee to the base value in order to adjust the compression characteristic to the audio signal if, after the limit value has been exceeded, the input level drops below the limit value again.

6. The method according to claim 1, which further comprises carrying out the compression of the audio signal by using at least one of a time constant for attack or a time constant for release being determined adaptively on a basis of the input level.

7. The method according to claim 6, which further comprises carrying out the comparison of the measured input level with the limit value over at least one of a longer attack time or a longer release time than the time constant of attack or the time constant of release for the compression.

8. The method according to claim 1, which further comprises:
breaking down the audio signal into a plurality of frequency bands in groups; and
in each group of frequency bands, for each frequency band in the group:
measuring an input level of a signal component of the audio signal in the frequency band;
comparing the measured input level with a frequency-band-specific limit value;
adjusting a compression characteristic prescribed for the frequency band to the signal component; and
compressing the signal component in accordance with the adjusted compression characteristic.

9. A signal processing unit to compress the dynamics in an audio signal fed in from a signal input, the signal processing unit configured to:
measure at least one input level of the audio signal;
compare the measured input level with a limit value;
adjust a prescribed compression characteristic having a knee defined by a base value of the input level to the audio signal by raising the knee from the base value to a higher target value if the at least one input level exceeds the limit value; and
compress the audio signal in accordance with the adjusted compression characteristic.

10. A hearing device or hearing aid, comprising:
at least one microphone for obtaining an audio signal from an ambient sound; and
the signal processing unit according to claim 9 connected to said microphone.
